(19) United States
(12) Patent Application Publication
(10) Pub. No.: US 2026/0198266 A1
(43) Pub. Date: Jul. 9, 2026

(54) PICKUP SYSTEM AND PICKUP METHOD

(71) Applicant: PANASONIC INTELLECTUAL PROPERTY MANAGEMENT CO., LTD., Osaka (JP)

(72) Inventors: Koji MOTOMURA, Fukuoka (JP); Masahiro KUBOTA, Fukuoka (JP); Fumio NAKAYAMA, Fukuoka (JP)

(21) Appl. No.: 19/132,987

(22) PCT Filed: Oct. 27, 2023
(86) PCT No.: PCT/JP2023/038926

§ 371 Date: May 27, 2025

(30) Foreign Application Priority Data
Dec. 6, 2022 (JP) 2022-195138

(51) Int. Cl. H10P 72/76; B25J 15/06; H10P 72/78

(52) U.S. Cl. CPC H10P 72/76; B25J 15/0616; H10P 72/78

(57) ABSTRACT

A pickup system includes: a pickup nozzle; a negative pressure generator that generates a negative pressure around the opening of the pickup nozzle; an ultrasonic generator that generates an ultrasonic wave from around the opening; and a controller. The controller causes the ultrasonic generator to start the generating of the ultrasonic wave when a distance from the opening of the pickup nozzle to a chip reaches, by the ascending and descending of the pickup nozzle, a distance specified beforehand, and causes the pickup nozzle to hold the chip in a non-contact manner using a suction force generated by the negative pressure around the opening and a repulsive force generated by the ultrasonic wave around the opening, and the distance specified is a distance that is specified according to the frequency of the ultrasonic wave generated by the ultrasonic generator.

### TECHNICAL FIELD

The present disclosure relates to a system which picks up components and the like.

### BACKGROUND ART

In order to achieve higher functionality in a semiconductor package, hybrid bonding which does not use bumps, bonding materials, and the like is required. In hybrid bonding, in a state where the surface of a semiconductor chip is cleaned, the semiconductor chip is bonded to a substrate or the like utilizing hydrogen bonding or the like. Hence, in hybrid bonding, it is necessary to keep the surface of the semiconductor chip highly clean after the semiconductor chip is picked up from a dicing tape which is an adhesive sheet until the semiconductor chip is bonded.

Conventionally, a pickup device using a vacuum type pickup nozzle has been proposed (see, for example, Patent Literature (PTL) 1). In the pickup device, when a semiconductor chip is picked up, a metallic pickup nozzle makes contact with the surface of the semiconductor chip. The contact may contaminate or damage the surface of the semiconductor chip. Consequently, the semiconductor chip disadvantageously cannot be properly bonded to a substrate. Hence, there is a need for a technique in which the pickup nozzle picks up the semiconductor chip in a non-contact manner.

### CITATION LIST

### Patent Literature

[PTL 1] Japanese Unexamined Patent Application Publication No. 2018-63967

### SUMMARY OF INVENTION

### Technical Problem

Disadvantageously, however, even when in the pickup device disclosed in PTL 1, the pickup nozzle holds the semiconductor chip in a non-contact manner, it may be difficult to appropriately pick up a component which is the semiconductor chip.

Hence, the present disclosure provides a pickup system which can appropriately pick up components.

### Solution to Problem

A pickup system according to an aspect of the present disclosure includes: a holding tool that includes an opening, and is configured to ascend and descend; a negative pressure generator that generates a negative pressure around the opening of the holding tool; an ultrasonic generator that generates an ultrasonic wave from around the opening; and a controller that controls the negative pressure generator and the ultrasonic generator, the controller: causes the ultrasonic generator to start the generating of the ultrasonic wave when a distance from the opening of the holding tool to a component adhered on an adhesive sheet reaches, by the ascending and descending of the holding tool, a distance specified beforehand; and causes the holding tool to hold the component in a non-contact manner using a suction force generated by the negative pressure around the opening and a repulsive force generated by the ultrasonic wave around the opening, and the distance specified is a distance that is specified according to a frequency of the ultrasonic wave generated by the ultrasonic generator.

These general or specific aspects may be realized by a system, a method, an integrated circuit, a computer program, or a computer-readable recording medium such as a CD-ROM, or may be realized by any combination of a system, a method, an integrated circuit, a computer program, and a recording medium. The recording medium may be a non-transitory recording medium.

### Advantageous Effects of Invention

The pickup system according to the present disclosure can appropriately pick up components.

Further advantages and effects in the aspect of the present disclosure will be apparent from the specification and drawings. Although such advantages and/or effects are provided by some embodiments and configurations described in the specification and drawings, not all of the configurations are necessarily required.

### BRIEF DESCRIPTION OF DRAWINGS

FIG. 1 is a perspective view of a component mounting device in Embodiment 1.

FIG. 2 is a diagram for illustrating an operation in which the component mounting device in Embodiment 1 mounts a chip on a substrate.

FIG. 3 is a diagram showing an example of the configuration of a pickup system in Embodiment 1.

FIG. 4 is a diagram for illustrating an example of a basic operation in which a pickup nozzle in Embodiment 1 picks up the chip.

FIG. 5 is a diagram showing an example of a case where the position of the chip adhered on an adhesive sheet is displaced.

FIG. 6 is a diagram showing an example of a timing at which the generation of ultrasonic waves is started in Embodiment 1.

FIG. 7 is a flowchart showing an example of a processing operation performed by a controller in Embodiment 1.

FIG. 8 is a diagram showing an example of the configuration of a component mounting device in Embodiment 2 and an example of an operation in which the component mounting device mounts a chip on a substrate.

FIG. 9 is a diagram showing an example of the configuration of a pickup system in Embodiment 2.

FIG. 10 is a diagram showing an example of collection of an error chip in Embodiment 2.

FIG. 11 is a flowchart showing an example of a processing operation performed by a controller in Embodiment 2.

FIG. 12 is a diagram showing another example of collection of the error chip in Embodiment 2.

FIG. 13 is a diagram showing an example of upward pushing of the chip.

FIG. 14 is a diagram showing another example of the upward pushing of the chip.

FIG. 15 is a diagram showing an example of the shape of an upward pushing pin.

FIG. 16 is a diagram showing still another example of the upward pushing of the chip.

### DESCRIPTION OF EMBODIMENTS

A pickup system according to a first aspect of the present disclosure includes: a holding tool that includes an opening, and is configured to ascend and descend; a negative pressure generator that generates a negative pressure around the opening of the holding tool; an ultrasonic generator that generates an ultrasonic wave from around the opening; and a controller that controls the negative pressure generator and the ultrasonic generator, the controller: causes the ultrasonic generator to start the generating of the ultrasonic wave when a distance from the opening of the holding tool to a component adhered on an adhesive sheet reaches, by the ascending and descending of the holding tool, a distance specified beforehand; and causes the holding tool to hold the component in a non-contact manner using a suction force generated by the negative pressure around the opening and a repulsive force generated by the ultrasonic wave around the opening, and the distance specified is a distance that is specified according to a frequency of the ultrasonic wave generated by the ultrasonic generator. The holding tool is, for example, a pickup nozzle.

In this way, when the distance from the opening of the holding tool to the component reaches the specified distance, the generation of the ultrasonic wave is started, and the specified distance is a distance which is specified according to the frequency of the ultrasonic wave. Here, when the ultrasonic wave is a standing wave, the frequency of the ultrasonic wave determines a position where vibrations are large in air serving as a medium through which the ultrasonic wave is transmitted and a position where vibrations are small. Hence, when the distance from the opening of the holding tool to the component reaches the specified distance, the generation of the ultrasonic wave is started, and thus at the time when the generation of the ultrasonic wave is started, the vibrations of air caused by the ultrasonic wave in the position of the component can be decreased. Consequently, the displacement of the component from the adhesive sheet caused by the vibrations of air is suppressed, and thus it is possible to cause the holding tool to appropriately hold the component.

In a second aspect dependent on the first aspect of the present disclosure, the distance specified may be a distance from the opening of the holding tool to a part other than an antinode of the ultrasonic wave generated by the ultrasonic generator.

In this way, the specified distance is the distance from the opening of the holding tool to the part other than the antinode of the ultrasonic wave, and thus the part (for example, a node) other than the antinode of the ultrasonic wave appears in the position of the component. Here, in the antinode of the ultrasonic wave, vibrations of air are large, and in the part other than the antinode, vibrations of air are small. Hence, at the time when the generation of the ultrasonic wave is started, vibrations of air caused by the ultrasonic wave in the position of the component can be effectively decreased. Consequently, the displacement of the component from the adhesive sheet is suppressed with high accuracy, and thus it is possible to cause the holding tool to appropriately hold the component.

In a third aspect dependent on the first or second aspect of the present disclosure, the controller may separate the component held by the holding tool from the holding tool by controlling vibrations of the ultrasonic wave generated by the ultrasonic generator in a state where the generating of the negative pressure by the negative pressure generator is suppressed.

In this way, the generation of the negative pressure is suppressed, and thus it is possible to decrease the suction force with which the holding tool sucks the component, and furthermore, the vibrations of ultrasonic wave is controlled, and thus it is possible to increase the repulsive force between the holding tool and the component. Consequently, the component can be effectively released from the holding tool. Although in order to release the component from the holding tool, it can be considered that air is discharged from the opening of the holding tool, air is discharged, and thus dust around the holding tool may be blown up. Then, when the dust which has been blown up is adhered to another component which is prepared to be mounted on a substrate, the dust may enter a joint between the component and the substrate to cause a joint failure. However, in the third aspect described above, air is not discharged, and thus it is possible to suppress the blowing up of dust.

In a fourth aspect dependent on the third aspect of the present disclosure, the controller may separate the component from the holding tool by suppressing the generating of the negative pressure by the negative pressure generator and then increasing a vibration frequency of the ultrasonic waves generated by the ultrasonic generator.

In this way, the vibration frequency of the ultrasonic wave is increased, and thus it is possible to appropriately increase the repulsive force between the holding tool and the component. Consequently, it is possible to more effectively separate the component from the holding tool.

In a fifth aspect dependent on the fourth aspect of the present disclosure, the controller may increase the vibration frequency of the ultrasonic wave generated by the ultrasonic generator when the component is not dropped from the holding tool after a predetermined time has elapsed since the generating of the negative pressure by the negative pressure generator is suppressed.

In this way, when the component is dropped within the predetermined time, the vibration frequency of the ultrasonic wave is not increased, and thus it is possible to suppress an unnecessary increase in the vibration frequency of the ultrasonic wave. When the vibration frequency of the ultrasonic wave is increased, dust may be blown up more slightly than the discharge of air. However, an increase in the vibration frequency of the ultrasonic wave is suppressed, and thus it is possible to further suppress the blowing up of dust.

In a sixth aspect dependent on any one of the first to fifth aspects of the present disclosure, the pickup system may further include an upward pusher that pushes the component adhered on the adhesive sheet upward from below via the adhesive sheet, and the controller may further control the upward pusher.

In this way, the peeling off of the component from the adhesive sheet can be facilitated by the upward pushing of the upward pusher, and thus it is possible to decrease the suction force generated by the negative pressure and the repulsive force generated by the ultrasonic wave. Consequently, it is possible to efficiently hold the component.

In a seventh aspect dependent on the sixth aspect of the present disclosure, the controller may start the generating of the ultrasonic wave performed by the ultrasonic generator when the component is pushed upward by the upward pusher.

In this way, even if the component is easily displaced from the adhesive sheet by the facilitation of the peeling off caused by the upward pushing, the generation of the ultrasonic wave is started when the distance from the opening of the holding tool to the component reaches the specified distance, and thus it is possible to suppress the displacement of the component. Consequently, it is possible to more efficiently hold the component.

In an eighth aspect dependent on the sixth or seventh aspect of the present disclosure, the upward pusher may include a plurality of upward pushing pins, and the controller may cause the plurality of upward pushing pins to push the component upward and then cause only one of the plurality of upward pushing pins to further push the component upward by controlling the upward pusher.

In this way, the component is pushed upward by only one upward pushing pin, and thus it is possible to easily adjust the inclination of the component with the tip end of the upward pushing pin used as a support point. Consequently, the surfaces of the component and the holding tool opposite each other can be parallel to each other, and thus it is possible to cause the holding tool to appropriately hold the component.

In a ninth aspect dependent on any one of the first to eighth aspects of the present disclosure, the controller may charge at least one of the opening of the holding tool or a surface of the component by controlling an electrical device to cause the opening of the holding tool and the surface of the component to have the same polarity, the surface facing the holding tool.

In this way, the surface of the opening of the holding tool and the surface of the component facing the holding tool have the same polarity, and thus it is possible to generate an electrical repulsive force therebetween. Consequently, it is possible to suppress contact between the component and the holding tool.

The general or specific aspects of the controller described above may be realized by a system, a method, an integrated circuit, a computer program, or a computer-readable recording medium such as a CD-ROM, or may be realized by any combination of a system, a method, an integrated circuit, a computer program, and a recording medium. The recording medium may be a non-transitory recording medium.

Embodiments will be specifically described below with reference to drawings.

Each of the embodiments described below indicates a general or specific example. Numerical values, shapes, materials, constituent elements, the arrangement and connection of the constituent elements, steps, the order of the steps, and the like shown in the following embodiments are examples, and are not intended to limit the present disclosure. Among the constituent elements in the following embodiments, constituent elements which are not recited in the independent claims indicating the highest level of concept are described as optional constituent elements.

The drawings are schematic views, and are not exactly shown. In the drawings, the same constituent members are identified with the same reference signs. In the following embodiments, expressions such as “approximately simultaneously” are used. For example, “approximately simultaneously” means not only “completely simultaneously” but also “substantially simultaneously”, and in other words, for example, “approximately simultaneously” means that a several percent error is included. In a range where effects in the present disclosure can be achieved, “approximately simultaneously” means simultaneously. The same is true for other expressions which use “simultaneously”.

### Embodiment 1

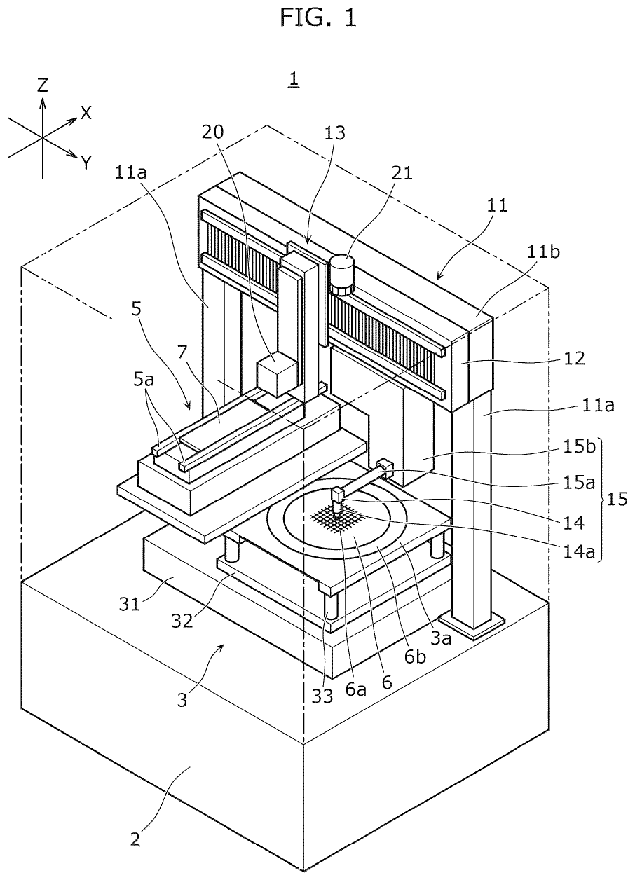

FIG. 1 is a perspective view of a component mounting device in the present embodiment.

Component mounting device 1 in the present embodiment picks up a component, and mounts the component picked up on substrate 7. Hence, component mounting device 1 in the present embodiment includes a pickup system which picks up the component. The mounting of the component on substrate 7 is also referred to as bonding of the component on substrate 7. Substrate 7 in the present embodiment is not limited to a specific type of substrate, and may be a silicon substrate, a silicon chip, or the like. In the present disclosure, a vertical direction is referred to as a Z axis direction or an up/down direction, and one direction in a plane perpendicular to the vertical direction is referred to as a Y axis direction, a left/right direction, or a lateral direction, and in the plane perpendicular thereto, a direction perpendicular to the Y axis direction is an X axis direction or a depth direction. In the present disclosure, a positive side in the Z axis direction is upward or up, and a negative side in the Z axis direction is downward or down. In the present disclosure, a positive side in the Y axis direction is a right side or right, and a negative side in the Y axis direction is a left side or left. In the present disclosure, a positive side in the X axis direction is a back side or back, and a negative side in the X axis direction is a front side or a front.

Component mounting device 1 includes base 2, component supplier 3, substrate holder 5, component holder 15, frame 11, Y axis driving mechanism 12, component mounter 13, and pickup camera 21. Base 2 is the base of component mounting device 1, and supports constituent members included in component mounting device 1.

Component supplier 3 is placed on base 2, and supplies the component to component holder 15. Component supplier 3 as described above includes holding table 3a, XY table mechanism 31, movement plate 32, and a plurality of support members 33. Holding table 3a holds semiconductor wafer unit 6 in a state where semiconductor wafer unit 6 is along a horizontal direction. Semiconductor wafer unit 6 includes adhesive sheet 6b and a plurality of chips 6a. Chips 6a are individual pieces or semiconductor chips obtained by dicing a semiconductor wafer, and are components which are supplied by component supplier 3 and mounted on substrate 7. Adhesive sheet 6b is a sheet which has adhesive properties. Chips 6a are adhered on the upper surface of adhesive sheet 6b. Each of support members 33 is a columnar member which is placed on movement plate 32 so as to stand upright from movement plate 32. Support members 33 support holding table 3a in a state where semiconductor wafer unit 6 held on holding table 3a is separated upward from movement plate 32. Movement plate 32 is a plate which is disposed in XY table mechanism 31. XY table mechanism 31 moves movement plate 32 in the X axis direction and in the Y axis direction. As movement plate 32 is moved, semiconductor wafer unit 6 is moved in the X axis direction and in the Y axis direction. In other words, chips 6a are moved along an XY plane.

Pickup camera 21 is disposed above component supplier 3, and images chip 6a to be picked up in semiconductor wafer unit 6.

Substrate holder 5 holds substrate 7 in a state where substrate 7 is along the horizontal direction. Substrate holder 5 as described above includes conveyance rail 5a. Substrate holder 5 locates and holds substrate 7 conveyed by conveyance rail 5a in a mounting position. The mounting position is a position in which chip 6a is mounted.

Component holder 15 includes arm 15a, pickup head movement mechanism 15b, and pickup head 14. Arm 15a is a columnar member, and is attached to pickup head movement mechanism 15b in a state where arm 15a is along the X axis direction. In other words, one end (that is, a base end) of arm 15a in a longitudinal direction is attached to pickup head movement mechanism 15b. Pickup head 14 is attached to the other end (that is, a tip end) of arm 15a.

Pickup head movement mechanism 15b is suspended from Y axis frame 11b of frame 11, and moves arm 15a in the X axis direction, in the Y axis direction, and in the Z axis direction. Furthermore, pickup head movement mechanism 15b rotates arm 15a about a center axis along the longitudinal direction of arm 15a. In other words, pickup head movement mechanism 15b rotates arm 15a around the X axis. Pickup head 14 is attached to the tip end of arm 15a as described above. Pickup head 14 includes pickup nozzle 14a which is made of, for example, metal and holds chip 6a by vacuum suction. Vacuum suction is the action of sucking air. Hence, pickup nozzle 14a is driven by pickup head movement mechanism 15b to move in the X axis direction, in the Y axis direction, and in the Z axis direction, and to rotate around the X axis. Pickup head movement mechanism 15b moves pickup nozzle 14a based on the result of imaging performed by pickup camera 21. In this way, pickup head movement mechanism 15b lowers pickup nozzle 14a to be able to accurately bring pickup nozzle 14a close to the upper surface of chip 6a to be picked up. Pickup nozzle 14a in the present embodiment is also simply referred to as a nozzle, and is an example of a holding tool which includes an opening for holding chip 6a by vacuum suction.

As described above, component holder 15 in the present embodiment uses the holding tool which is pickup nozzle 14a that includes an opening, and is configured to ascend and descend, and thereby holds chip 6a adhered on adhesive sheet 6b from above.

Frame 11 is disposed on base 2 on the positive side in the X axis direction, and includes two support posts 11a and long Y axis frame 11b. Two support posts 11a support Y axis frame 11b in a state where Y axis frame 11b is along the Y axis direction and is separated upward from the upper surface of base 2. In other words, Y axis frame 11b is suspended by two support posts 11a. As described above, pickup head movement mechanism 15b is suspended from Y axis frame 11b.

Y axis driving mechanism 12 is attached to the surface of Y axis frame 11b on the negative side in the X axis direction, and moves component mounter 13 in the Y axis direction. Component mounter 13 includes mounting unit 20. Component mounter 13 uses mounting unit 20 to receive, from pickup nozzle 14a, chip 6a held by pickup nozzle 14a, and mounts chip 6a on substrate 7 located in the mounting position.

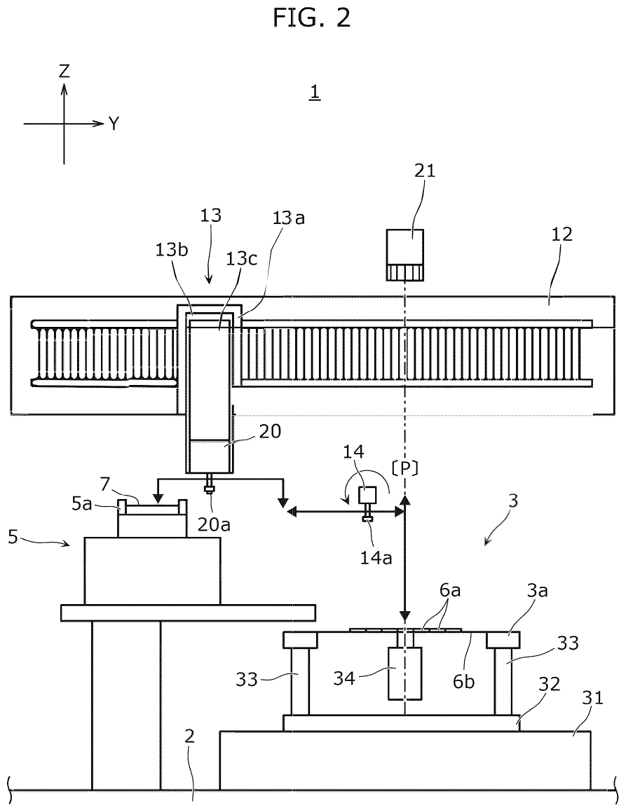

FIG. 2 is a diagram for illustrating an operation in which component mounting device 1 mounts chip 6a on substrate 7.

Component mounting device 1 picks up, among chips 6a adhered on adhesive sheet 6b, chip 6a disposed in pickup operation position P which is previously set in the XY plane, and mounts chip 6a on substrate 7.

Specifically, XY table mechanism 31 moves movement plate 32 in the X axis direction and in the Y axis direction to dispose chip 6a to be picked up in pickup operation position P. Chip 6a to be picked up which is disposed in pickup operation position P is pushed upward by upward pusher 34.

In other words, as shown in FIG. 2, component mounting device 1 in the present embodiment includes upward pusher 34 disposed in pickup operation position P. Upward pusher 34 may be included in component supplier 3. Upward pusher 34 pushes chip 6a adhered on adhesive sheet 6b upward from below via adhesive sheet 6b. Specifically, upward pusher 34 pushes upward chip 6a to be picked up which is disposed in pickup operation position P.

Pickup camera 21 is disposed above component supplier 3 and in pickup operation position P. Pickup camera 21 as described above images pickup operation position P and an area therearound from above component supplier 3 among chips 6a adhered on adhesive sheet 6b. In this way, chip 6a to be picked up is imaged, and the position of chip 6a to be picked up is recognized based on the result of the imaging. In other words, position recognition is performed on chip 6a.

Pickup nozzle 14a of pickup head 14 is driven by pickup head movement mechanism 15b to move downward, approaches, from above, chip 6a the position of which has been recognized based on the result of the imaging performed by pickup camera 21, and holds chip 6a described above. Then, pickup nozzle 14a is moved upward in a state where pickup nozzle 14a holds chip 6a, and is further moved to, for example, the negative side in the Y axis direction. Here, pickup nozzle 14a directs the lower surface (that is, the bottom surface) of chip 6a held upward by the rotation of arm 15a performed by pickup head movement mechanism 15b. In this way, chip 6a is held by pickup nozzle 14a in an upside-down state.

As shown in FIG. 2, component mounter 13 includes not only mounting unit 20 described above but also movement plate 13a, ascent/descent mechanism 13b, and ascent/descent plate 13c. Movement plate 13a is a plate which is attached to Y axis driving mechanism 12 movably in the Y axis direction. In other words, movement plate 13a is driven by Y axis driving mechanism 12 to move in the Y axis direction.

Ascent/descent mechanism 13b is attached to the front surface of movement plate 13a to cause ascent/descent plate 13c to ascend and descend. Mounting unit 20 is attached to a lower part of ascent/descent plate 13c. Mounting unit 20 includes component mounting nozzle 20a. Component mounting nozzle 20a receives chip 6a, for example, from pickup nozzle 14a which holds chip 6a in an upside-down state. For example, component mounting nozzle 20a is driven by each of Y axis driving mechanism 12 and ascent/descent mechanism 13b to move above chip 6a, and holds chip 6a, for example, by vacuum suction. Then, component mounting nozzle 20a is moved to the side of substrate 7 along the Y axis direction in a state where component mounting nozzle 20a holds chip 6a, and mounts chip 6a on substrate 7.

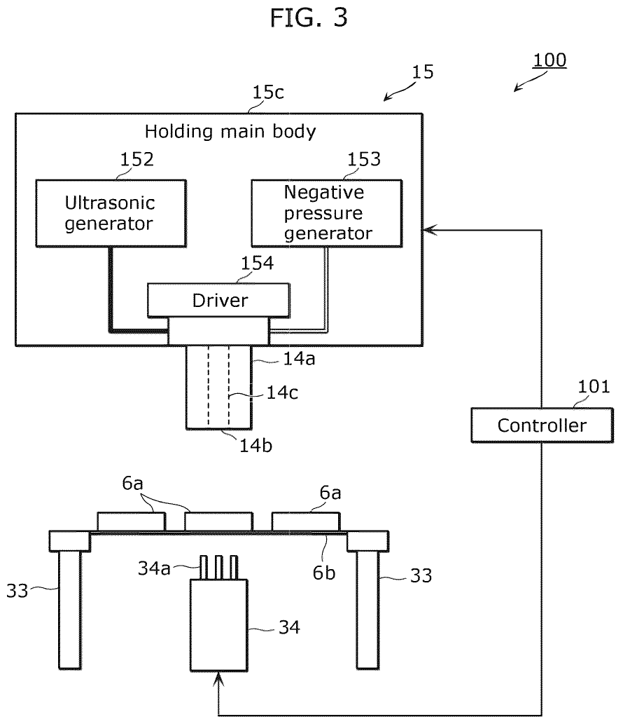

FIG. 3 is a diagram showing an example of the configuration of the pickup system in the present embodiment.

Pickup system 100 in the present embodiment is a system which is included in component mounting device 1, and includes, for example, component holder 15 described above, upward pusher 34, and controller 101.

Component holder 15 includes holding main body 15c and pickup nozzle 14a. Holding main body 15c includes, for example, arm 15a described above, pickup head movement mechanism 15b, and a part of pickup head 14 other than pickup nozzle 14a. Holding main body 15c includes ultrasonic generator 152, negative pressure generator 153, and driver 154.

Ultrasonic generator 152 vibrates (that is, ultrasonically vibrates) pickup nozzle 14a to generate ultrasonic waves from around opening 14b of pickup nozzle 14a. In other words, pickup nozzle 14a ultrasonically vibrates in the up/down direction to transmit the resulting vibrations to air in contact with the lower surface of pickup nozzle 14a. For example, ultrasonic generator 152 ultrasonically vibrates pickup nozzle 14a with an amplitude of about 10 to 20 μm at maximum.

Negative pressure generator 153 generates a negative pressure around opening 14b of pickup nozzle 14a. In the present embodiment, negative pressure generator 153 is configured, for example, as a vacuum pump. Negative pressure generator 153 as described above is a flow path formed in pickup nozzle 14a, and causes a negative pressure in flow path 14c of air communicating with opening 14b to generate the negative pressure around opening 14b. In other words, negative pressure generator 153 sucks air around opening 14b via flow path 14c to generate the negative pressure around opening 14b.

Driver 154 includes, for example, a motor or the like to move pickup nozzle 14a in the X axis direction, in the Y axis direction, and in the Z axis direction. Driver 154 rotates arm 15a to rotate pickup nozzle 14a of pickup head 14 attached to the tip end of arm 15a. Driver 154 as described above may be incorporated in pickup head movement mechanism 15b.

Upward pusher 34 includes a plurality of upward pushing pins 34a, and causes upward pushing pins 34a to ascend and descend. Upward pushing pins 34a are moved upward to push up adhesive sheet 6b, and thus chip 6a adhered on adhesive sheet 6b is pushed upward.

Controller 101 controls upward pusher 34 and component holder 15. In other words, controller 101 controls upward pusher 34, driver 154, ultrasonic generator 152, and negative pressure generator 153.

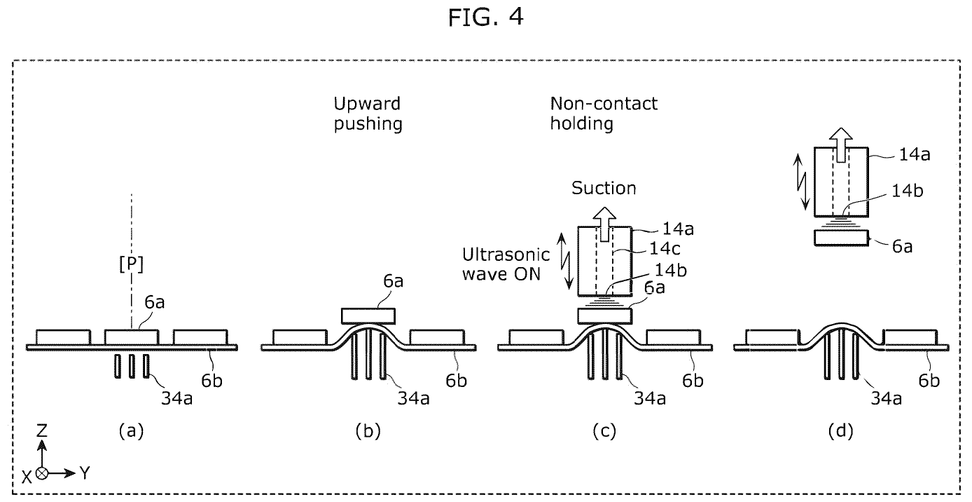

FIG. 4 is a diagram for illustrating an example of a basic operation in which pickup nozzle 14a in the present embodiment picks up chip 6a.

XY table mechanism 31 moves movement plate 32, and thus adhesive sheet 6b held on holding table 3a is moved in the X axis direction and in the Y axis direction. As shown in part (a) in FIG. 4, by the movement of adhesive sheet 6b, chip 6a to be picked up is disposed in pickup operation position P. In other words, chip 6a to be picked up is disposed on upward pushing pins 34a of upward pusher 34.

Then, as shown in part (b) in FIG. 4, upward pusher 34 moves upward pushing pins 34a upward to push chip 6a upward via adhesive sheet 6b. Chip 6a is pushed upward via adhesive sheet 6b as described above, and thus chip 6a is easily peeled off from adhesive sheet 6b. In other words, the peeling off of chip 6a from adhesive sheet 6b is facilitated. By sucking adhesive sheet 6b from below together with the upward pushing of chip 6a, the peeling off of chip 6a may further be facilitated.

Then, as shown in part (c) in FIG. 4, pickup nozzle 14a is moved downward to held, in a non-contact manner, chip 6a which has been pushed upward. In other words, pickup nozzle 14a uses a suction force which draws chip 6a to the side of opening 14b of pickup nozzle 14a and a repulsive force which moves chip 6a away from opening 14b to hold chip 6a in a non-contact manner. The suction force is obtained by the generation of the negative force performed by negative pressure generator 153. For example, a distance by which chip 6a can be sucked by the suction force, that is, a distance from pickup nozzle 14a to chip 6a is about 0.05 to 1.0 mm. The repulsive force is obtained by the generation of ultrasonic waves performed by ultrasonic generator 152.

Here, in the present embodiment, chip 6a adhered on adhesive sheet 6b is pushed upward from below via adhesive sheet 6b. Hence, it is possible to facilitate the peeling off of chip 6a from adhesive sheet 6b to decrease the suction force generated by the negative pressure and the repulsive force generated by the ultrasonic waves. Consequently, it is possible to efficiently hold chip 6a.

Then, as shown in part (d) in FIG. 4, pickup nozzle 14a is driven by driver 154 to move upward in a state where pickup nozzle 14a holds chip 6a in a non-contact manner.

Here, the position of chip 6a adhered on adhesive sheet 6b may be displaced depending on the timing at which ultrasonic waves are generated by ultrasonic generator 152. In such a case, pickup nozzle 14a cannot hold chip 6a in an appropriate state.

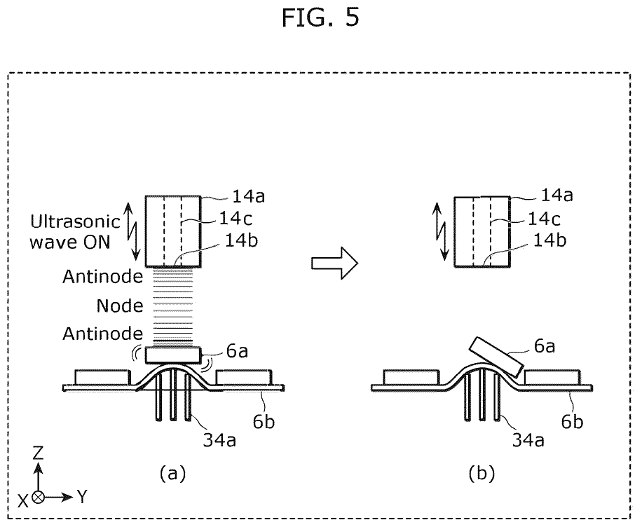

FIG. 5 is a diagram showing an example of a case where the position of chip 6a adhered on adhesive sheet 6b is displaced.

As described above, ultrasonic generator 152 generates ultrasonic waves from around opening 14b of pickup nozzle 14a. The ultrasonic waves generated in this way are compression waves which travel toward chip 6a and are reflected off the upper surface of chip 6a. Consequently, the ultrasonic waves are formed as standing waves. Hence, the ultrasonic wave has nodes and antinodes, and the positions of the nodes and the antinodes are fixed and do not vary over time. At the antinodes of the ultrasonic wave, vibrations of air which is the medium of sound are large. On the other hand, at the nodes of the ultrasonic wave, vibrations of air are small.

Since chip 6a which receives ultrasonic waves is pushed upward by upward pushing pins 34a, chip 6a is easily peeled off from adhesive sheet 6b.

Therefore, when the generation of ultrasonic waves is started while pickup nozzle 14a is being moved downward, for example, if the upper surface of chip 6a is located in a position where the antinode of the ultrasonic wave is assumed to appear as in part (a) in FIG. 5, chip 6a is significantly shaken by large vibrations of air. Consequently, as shown in part (b) in FIG. 5, chip 6a is displaced from adhesive sheet 6b. When chip 6a is displaced as described above, pickup nozzle 14a cannot hold chip 6a in an appropriate state.

Hence, controller 101 in the present embodiment causes ultrasonic generator 152 to start the generation of ultrasonic waves when the upper surface of chip 6a is located in a position where the node of the ultrasonic wave appears.

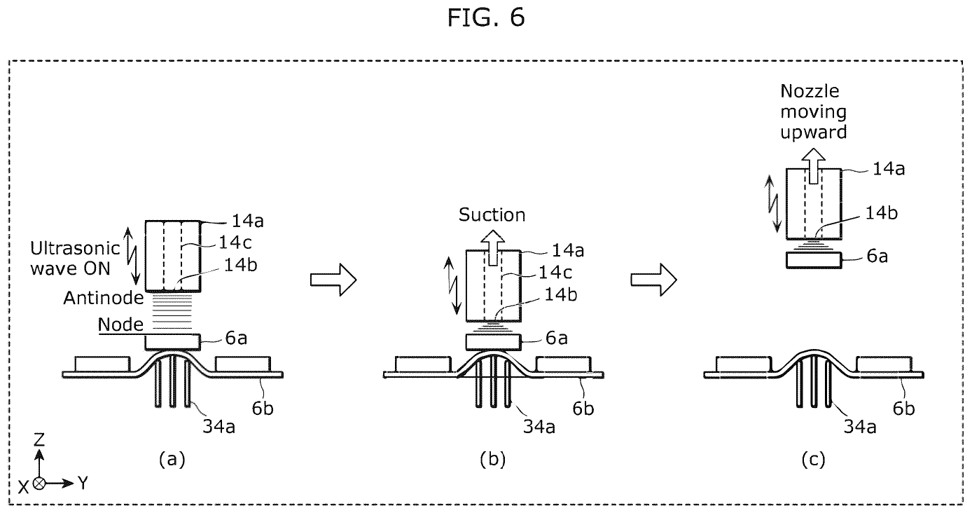

FIG. 6 is a diagram showing an example of a timing at which the generation of ultrasonic waves is started in the present embodiment.

Controller 101 controls driver 154 to move pickup nozzle 14a downward, and thereby brings pickup nozzle 14a close to chip 6a which has been pushed upward by upward pushing pins 34a. Then, as shown in part (a) in FIG. 6, when the upper surface of chip 6a is located in the position where the node of the ultrasonic wave appears, controller 101 causes ultrasonic generator 152 to start the generation of ultrasonic waves. The position where the node of the ultrasonic wave appears is specified according to the frequency of ultrasonic waves.

Specifically, between pickup nozzle 14a and chip 6a, a node appears every ½ wavelength of the ultrasonic wave, and an antinode appears every ½ wavelength of the ultrasonic wave. An antinode appears at the midpoint of two nodes adjacent to each other, and a node appears at the midpoint of two antinodes adjacent to each other. The wavelength of the ultrasonic wave is obtained by dividing the speed of the ultrasonic wave by the frequency (that is, the vibration frequency) of the ultrasonic wave. For example, the speed of the ultrasonic wave in air of 20° C. is 343.5 m. Hence, when the frequency of the ultrasonic wave is 35.2 kHz (that is, 35200 Hz), the wavelength of the ultrasonic wave is 343.5 (m)/35200 (Hz)=10 (mm). Since ultrasonic waves are generated from around opening 14b of pickup nozzle 14a, the antinode of the ultrasonic wave appears around opening 14b, and the node of the ultrasonic wave appears in a position a ¼ wavelength away from the antinode to the side of chip 6a. When the wavelength is 10 mm, the node of the ultrasonic wave appears in a position 2.5 mm away from opening 14b of pickup nozzle 14a to the side of chip 6a.

Hence, when the upper surface of chip 6a is located in the position 2.5 mm away from opening 14b of pickup nozzle 14a to the side of chip 6a, controller 101 causes ultrasonic generator 152 to start the generation of ultrasonic waves. In this way, not the antinode but the node of the ultrasonic wave appears on the upper surface of chip 6a, and thus it is possible to suppress the shaking of chip 6a caused by vibrations of air. Consequently, the displacement of chip 6a from adhesive sheet 6b is suppressed, and thus it is possible to stabilize chip 6a.

In the example of part (a) in FIG. 6, when the upper surface of chip 6a is located in the position where the node of the ultrasonic wave appears, controller 101 causes ultrasonic generator 152 to start the generation of ultrasonic waves. However, the timing at which the generation of ultrasonic waves is started is not limited to the timing in this example. When the upper surface of chip 6a is located in a position where the antinode of the ultrasonic wave does not appear, controller 101 may cause ultrasonic generator 152 to start the generation of ultrasonic waves.

In other words, controller 101 in the present embodiment causes ultrasonic generator 152 to start the generation of ultrasonic waves when the distance from opening 14b of pickup nozzle 14a serving as the holding tool to chip 6a adhered on adhesive sheet 6b reaches, by the ascending and descending of pickup nozzle 14a, a distance specified beforehand. The specified distance is a distance which is specified according to the frequency of the ultrasonic wave generated by ultrasonic generator 152. Specifically, the specified distance is a distance from opening 14b of pickup nozzle 14a to a part other than the antinode of the ultrasonic wave generated by ultrasonic generator 152. The position where the antinode of the ultrasonic wave appears and the position where the node of the ultrasonic wave appears are specified by the temperature of air serving as a medium for transmitting the ultrasonic wave and the frequency of the ultrasonic wave. The part other than the antinode may be the node as in the example of part (a) in FIG. 6, or may be a predetermined range about the position of the node which does not include the antinode. The predetermined range may be, for example, a range of a ¼ wavelength.

Then, as shown in part (b) in FIG. 6, controller 101 controls driver 154 to further lower pickup nozzle 14a. For example, driver 154 lowers pickup nozzle 14a at a speed of 5 mm/second. Driver 154 brings pickup nozzle 14a close to chip 6a such that the distance from the lower surface of pickup nozzle 14a to the upper surface of chip 6a is 100 to 200 μm. Then, controller 101 causes negative pressure generator 153 to start the suction of air. In this way, the negative pressure is generated around opening 14b of pickup nozzle 14a. Consequently, controller 101 uses the suction force generated by the negative pressure around opening 14b and the repulsive force generated by ultrasonic waves around opening 14b, and thereby causes pickup nozzle 14a to hold chip 6a in a non-contact manner. In the non-contact holding as described above, for example, a gap having a width of about 25 μm is generated between pickup nozzle 14a and chip 6a.

Thereafter, as shown in part (c) in FIG. 6, controller 101 controls driver 154 to move pickup nozzle 14a upward.

As described above, in the present embodiment, when the distance from opening 14b of pickup nozzle 14a to chip 6a reaches the specified distance, the generation of ultrasonic waves is started. The specified distance is a distance from opening 14b of pickup nozzle 14a to the node of the ultrasonic wave. Hence, at the time when the generation of ultrasonic waves is started, the node of the ultrasonic wave appears in the position of chip 6a. Here, vibrations of air are large at the antinode of the ultrasonic wave, and vibrations of air are small at the node thereof. Therefore, at the time when the generation of ultrasonic waves is started, vibrations of air caused by the ultrasonic wave in the position of chip 6a can be effectively decreased. Consequently, the displacement of chip 6a from adhesive sheet 6b is suppressed with high accuracy, and thus it is possible to cause pickup nozzle 14a to hold chip 6a more appropriately.

In other words, when pickup nozzle 14a is lowered, if as in the example of part (a) in FIG. 5, the generation of ultrasonic waves is started earlier than in the example of part (a) in FIG. 6, chip 6a is displaced from adhesive sheet 6b. Even if ultrasonic waves are generated at a timing earlier than in the example of part (a) in FIG. 5, that is, even if ultrasonic waves are generated when pickup nozzle 14a is further separated upward from chip 6a, pickup nozzle 14a is lowered, and thus a situation shown in the example of part (a) in FIG. 5 is caused. Hence, chip 6a is displaced from adhesive sheet 6b. However, in the present embodiment, as in the example of part (a) in FIG. 6, the generation of ultrasonic waves is started at the timing based on the specified distance, and thus it is possible to suppress the displacement of chip 6a from adhesive sheet 6b. More specifically, the specified distance is a distance from opening 14b of pickup nozzle 14a to the first node of the ultrasonic wave. Hence, even if pickup nozzle 14a is further lowered, as long as pickup nozzle 14a does not make contact with chip 6a, the upper surface of chip 6a is prevented from being located in the position where the antinode of the ultrasonic wave is assumed to appear. Since pickup nozzle 14a is close to chip 6a when the generation of ultrasonic waves is started, chip 6a can be drawn to pickup nozzle 14a by the suction force generated by the negative pressure. Therefore, even if pickup nozzle 14a is further lowered, the displacement of chip 6a from adhesive sheet 6b is suppressed, and thus it is possible to stabilize chip 6a.

In the present embodiment, a so-called ultrasonic non-contact chuck is realized by the generation of ultrasonic waves performed by ultrasonic generator 152. In other words, the repulsive force is obtained by a squeeze effect caused by the generation of ultrasonic waves, and thus it is possible to easily obtain an appropriate repulsive force. Consequently, it is possible to efficiently hold chip 6a in a non-contact manner.

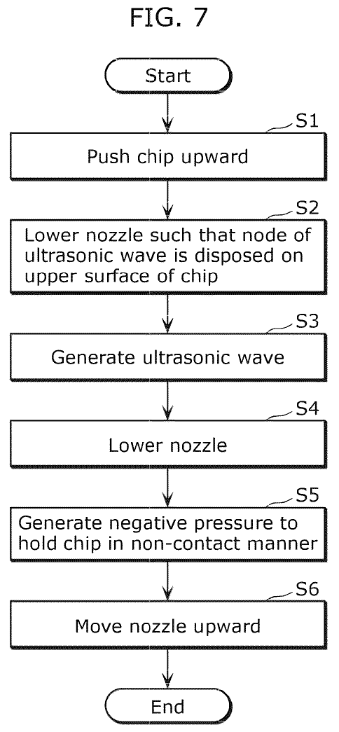

FIG. 7 is a flowchart showing an example of a processing operation performed by controller 101 in the present embodiment.

Controller 101 first causes upward pusher 34 to start the upward pushing of chip 6a (step S1).

Then, controller 101 controls driver 154 such that the node of the ultrasonic wave generated by ultrasonic generator 152 in step S3 which will be described later is located on the upper surface of chip 6a, and thereby lowers pickup nozzle 14a (step S2). In other words, controller 101 lowers pickup nozzle 14a to set the distance from opening 14b of pickup nozzle 14a to chip 6a adhered on adhesive sheet 6b to the specified distance described above.

Then, when the distance from opening 14b of pickup nozzle 14a to chip 6a reaches the specified distance, controller 101 causes ultrasonic generator 152 to start the generation of ultrasonic waves (step S3). Here, the significant shaking of chip 6a caused by the ultrasonic waves is suppressed, and thus it is possible to suppress the displacement of chip 6a from adhesive sheet 6b.

Then, controller 101 controls driver 154 to further lower pickup nozzle 14a (step S4). In steps S2 to S4, pickup nozzle 14a may be lowered without being stopped. Then, controller 101 causes negative pressure generator 153 to generate the negative pressure, and causes pickup nozzle 14a to hold chip 6a in a non-contact manner (step S5). In other words, controller 101 causes negative pressure generator 153 to generate the negative pressure to generate the suction force described above. Then, controller 101 uses the suction force which draws chip 6a to the side of opening 14b of pickup nozzle 14a and the repulsive force which moves chip 6a away from opening 14b, and thereby causes pickup nozzle 14a to hold chip 6a in a non-contact manner.

Thereafter, controller 101 controls driver 154 to move pickup nozzle 14a upward (step S6).

As described above, in the present embodiment, after chip 6a is pushed upward, the negative pressure with which pickup nozzle 14a holds chip 6a in a non-contact manner is generated. Hence, chip 6a is pushed upward, thus the peeling off of chip 6a from adhesive sheet 6b is facilitated, and thereafter, the negative pressure is generated, with the result that it is possible to decrease the negative pressure.

In the present embodiment, the so-called ultrasonic non-contact chuck is realized by the generation of ultrasonic waves performed by ultrasonic generator 152. In other words, the repulsive force is obtained by the squeeze effect caused by the generation of ultrasonic waves, and thus it is possible to easily obtain an appropriate repulsive force. Consequently, it is possible to efficiently hold chip 6a in a non-contact manner.

In the present embodiment, when chip 6a is pushed upward by upward pusher 34, controller 101 causes ultrasonic generator 152 to start the generation of ultrasonic waves. In this way, after the peeling off of chip 6a from adhesive sheet 6b is facilitated by the upward pushing of chip 6a, vibrations of air caused by ultrasonic waves can be further provided to chip 6a, with the result that the peeling off of chip 6a can be further facilitated. Consequently, it is possible to decrease the negative pressure generated by negative pressure generator 153. Even if chip 6a is easily displaced from adhesive sheet 6b by facilitating the peeling caused by the upward pushing, the generation of ultrasonic waves is started when the distance from opening 14b of pickup nozzle 14a to chip 6a reaches the specified distance, and thus it is possible to suppress the displacement of chip 6a. Consequently, it is possible to more efficiently hold chip 6a.

### Embodiment 2

A pickup system in the present embodiment further performs an additional operation for appropriately picking up chip 6a in addition to the operation of pickup system 100 in Embodiment 1.

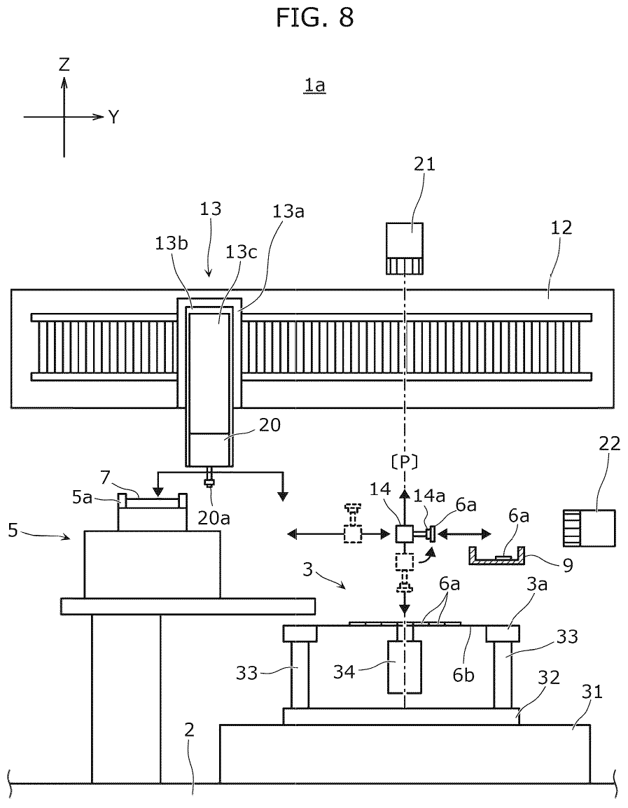

FIG. 8 is a diagram showing an example of the configuration of a component mounting device in the present embodiment and an example of an operation in which the component mounting device mounts chip 6a on substrate 7.

Component mounting device 1a in the present embodiment includes, as shown in FIG. 8, constituent elements included in component mounting device 1 in Embodiment 1, determination camera 22, and collection box 9. Determination camera 22 images chip 6a heled by pickup nozzle 14a. In an image captured by the imaging performed by determination camera 22, chip 6a is shown. Then, when chip 6a shown in the captured image is determined to be defective by performing image analysis on the captured image, defective chip 6a is discarded or collected. Collection box 9 is, for example, a lidless box for collecting defective chip 6a. Defective chip 6a is also referred to as an error chip. In FIG. 8 and the like, collection box 9 is shown as a cross-sectional view taken along a YZ plane so that chip 6a collected in collection box 9 can be easily recognized.

Specifically, when pickup nozzle 14a is moved upward while holding chip 6a in a non-contact manner, pickup nozzle 14a is rotated, for example, 90 degrees around the X axis. In this way, the lower surface of chip 6a is directed to determination camera 22. The lower surface of chip 6a is a surface which was adhered on adhesive sheet 6b, and is a surface on a side opposite to the upper surface held by pickup nozzle 14a. When the lower surface of chip 6a is directed to determination camera 22, determination camera 22 images the lower surface of chip 6a to output a captured image. When there is a scratch, a chip, dirt, or the like on the lower surface of chip 6a shown in the captured image, chip 6a is determined to be an error chip. Consequently, pickup nozzle 14a is driven by driver 154 to move above collection box 9, releases chip 6a determined to be an error chip, and drops it into collection box 9. On the other hand, when chip 6a is determined not to be an error chip, pickup nozzle 14a is rotated around the X axis to lift chip 6a upward, and passes chip 6a to component mounting nozzle 20a.

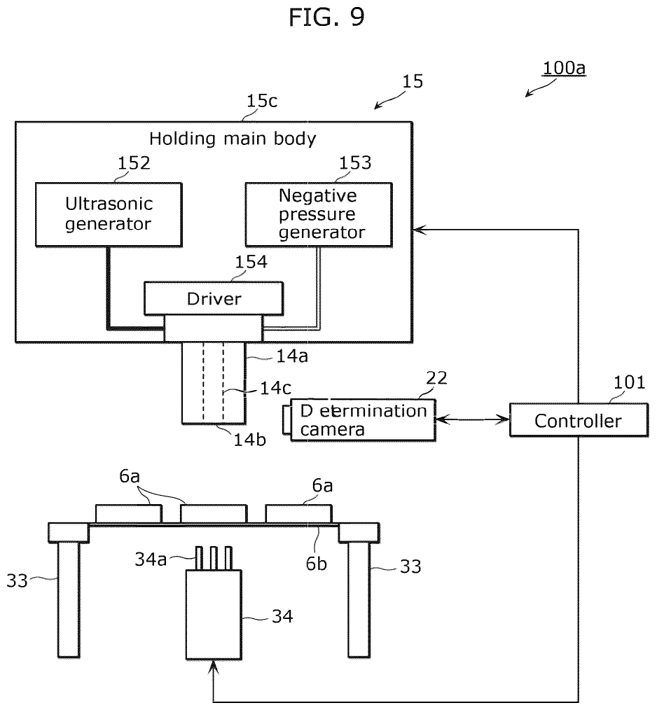

FIG. 9 is a diagram showing an example of the configuration of the pickup system in the present embodiment.

Pickup system 100a in the present embodiment is a system which is included in component mounting device 1a, includes, as in Embodiment 1, component holder 15, upward pusher 34, and controller 101, and further includes determination camera 22 described above.

Controller 101 in the present embodiment controls determination camera 22 to perform the image analysis on the image captured by the imaging performed by determination camera 22. In other words, controller 101 determines whether chip 6a shown in the captured image is an error chip. Then, controller 101 controls driver 154 based on the result of the determination. Specifically, controller 101 causes pickup nozzle 14a to perform the collection of the error chip into collection box 9 or the passing of chip 6a from pickup nozzle 14a to component mounting nozzle 20a.

Here, in the collection of the error chip into collection box 9, controller 101 suppresses the generation of the negative pressure by negative pressure generator 153. In an example, controller 101 stops the generation of the negative pressure. However, it is likely that simply stopping the generation of the negative pressure does not cause the error chip to leave pickup nozzle 14a, and thus the error chip is not collected into collection box 9. In such a case, if air in flow path 14c of pickup nozzle 14a is adjusted to have a positive pressure and, air is discharged from opening 14b of pickup nozzle 14a, it is possible to release the error chip from pickup nozzle 14a by the discharge of air. However, if air is discharged in component mounting device 1a, dust may be blown up in component mounting device 1a. Then, when the dust which has been blown up is adhered to separate chip 6a that is prepared to be mounted on substrate 7, the dust may enter a joint between chip 6a and substrate 7 to cause a joint failure. Chip 6a described above may also be determined to be an error chip to be collected. In the discharge of air, the pickup system needs to further include a facility such as piping for adjusting the air in flow path 14c of pickup nozzle 14a such that the air has a positive pressure, with the result that the configuration of the pickup system is disadvantageously complicated.

When the generation of the negative pressure is stopped, even if the generation of ultrasonic waves is simply continued, it is likely that an error chip is not released from pickup nozzle 14a. Possible causes include static electricity, residual pressure, ultrasonic waves, and the like. For example, even when the generation of the negative pressure is stopped, the negative pressure may be left as residual pressure for a while. The ultrasonic waves may generate a small negative pressure around opening 14b of pickup nozzle 14a. Hence, even when the generation of the negative pressure is stopped, in particular, thin chip 6a or the like is unlikely to drop by its own weight, with the result that it is likely that chip 6a is not separated from pickup nozzle 14a.

Hence, controller 101 in the present embodiment controls ultrasonic generator 152 to increase the vibrations of ultrasonic waves generated from around opening 14b of pickup nozzle 14a. In other words, ultrasonic generator 152 generates ultrasonic waves of larger vibrations than the ultrasonic waves used when chip 6a is held in a non-contact manner. In this way, a repulsive force which moves an error chip away from opening 14b is significantly exerted, and thus an error chip can be dropped from pickup nozzle 14a to be collected. In this case, air is not discharged, and thus it is possible to suppress the blowing up of dust.

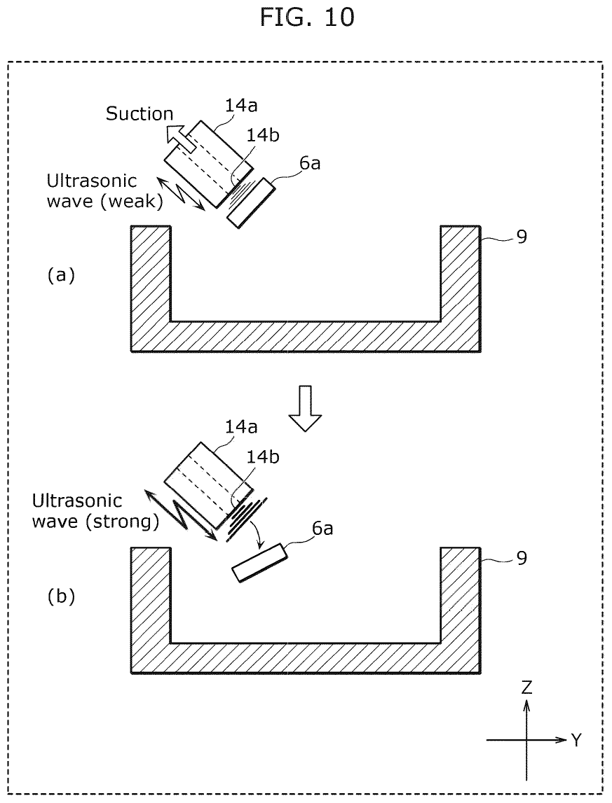

FIG. 10 is a diagram showing an example of the collection of an error chip.

Controller 101 controls driver 154 to move pickup nozzle 14a in the Y axis direction, and disposes, as shown in part (a) in FIG. 10, chip 6a determine to be an error chip above collection box 9. Then, controller 101 sets pickup nozzle 14a to a chip collection state by the rotation of pickup nozzle 14a around the X axis performed by driver 154. In the chip collection state, opening 14b of pickup nozzle 14a is directed, for example, 45 degrees upward from a downward direction in the Z axis direction. Here, the negative pressure is generated by the suction, and ultrasonic waves are also generated.

Then, controller 101 controls, as shown in part (b) in FIG. 10, negative pressure generator 153 and ultrasonic generator 152 to stop the generation of the negative pressure and to increase the vibrations of ultrasonic waves. Ultrasonic generator 152 controlled by controller 101 may increase the vibration frequency (that is, the frequency) of ultrasonic waves, or may increase the amplitude of ultrasonic waves. In this way, a repulsive force which moves chip 6a serving as the error chip away from opening 14b is significantly exerted, and thus the error chip is dropped from pickup nozzle 14a. Then, the dropped error chip is collected into collection box 9.

As described above, controller 101 in the present embodiment controls the vibrations of ultrasonic waves generated by ultrasonic generator 152 in a state where the generation of the negative pressure by negative pressure generator 153 is suppressed, and thereby releases chip 6a held by pickup nozzle 14a from pickup nozzle 14a. In this way, the generation of the negative pressure is suppressed, and thus it is possible to decrease the suction force with which pickup nozzle 14a sucks chip 6a, and furthermore, the vibrations of ultrasonic waves is controlled, and thus it is possible to increase the repulsive force between pickup nozzle 14a and chip 6a. Consequently, chip 6a can be effectively released from pickup nozzle 14a. Although in the discharge of air, dust may be blown up, in the present embodiment, air is not discharged, and thus it is possible to suppress the blowing up of dust. Consequently, it is possible to suppress the occurrence of the joint failure between other chip 6a and substrate 7 as described above. Furthermore, since there is no need to further provide a facility for discharging air, it is possible to suppress the complication of the configuration of pickup system 100a.

Specifically, controller 101 suppresses the generation of the negative pressure by negative pressure generator 153, and then increases the vibration frequency of ultrasonic waves generated by ultrasonic generator 152 to release chip 6a from pickup nozzle 14a. In this way, the vibration frequency of ultrasonic waves is increased, and thus it is possible to appropriately increase the repulsive force between pickup nozzle 14a and chip 6a. Consequently, it is possible to more effectively release chip 6a from pickup nozzle 14a. Although in the example described above, the generation of the negative pressure is suppressed, and then the vibration frequency of ultrasonic waves is increased, after the vibration frequency of ultrasonic waves is increased, the generation of the negative pressure may be suppressed in a reverse order. The generation of the negative pressure may be suppressed simultaneously with the increase in the vibration frequency of ultrasonic waves.

Controller 101 may further shift the timing at which the vibrations of ultrasonic waves are increased to a timing after the stop of the generation of the negative pressure. Specifically, controller 101 causes negative pressure generator 153 to stop the generation of the negative pressure, and then determines whether chip 6a is dropped from pickup nozzle 14a within a predetermined time. When controller 101 determines that chip 6a is dropped within the predetermined time, controller 101 causes ultrasonic generator 152 to stop the generation of ultrasonic waves. On the other hand, when controller 101 determines that chip 6a is not dropped after the predetermined time has elapsed, controller 101 causes ultrasonic generator 152 to increase the vibrations of ultrasonic waves. Here, controller 101 may determine whether chip 6a is dropped based on the result of the imaging of chip 6a performed by determination camera 22. When a pressure gauge or the like is provided in collection box 9, controller 101 may determine whether chip 6a is dropped according to a pressure measured with the pressure gauge.

As described above, when chip 6a is not dropped from pickup nozzle 14a after the predetermined time has elapsed since the generation of the negative pressure by negative pressure generator 153 is suppressed, controller 101 in the present embodiment may increase the vibration frequency of ultrasonic waves generated by ultrasonic generator 152. In this way, when chip 6a is dropped within the predetermined time, the vibration frequency of ultrasonic waves is not increased, with the result that it is possible to suppress an unnecessary increase in the vibration frequency of ultrasonic waves. Consequently, it is possible to suppress the burden of the processing operation. When the vibration frequency of ultrasonic waves is increased, dust may be blown up more slightly than the discharge of air. However, an increase in the vibration frequency of ultrasonic waves is suppressed, and thus it is possible to further suppress the blowing up of dust.

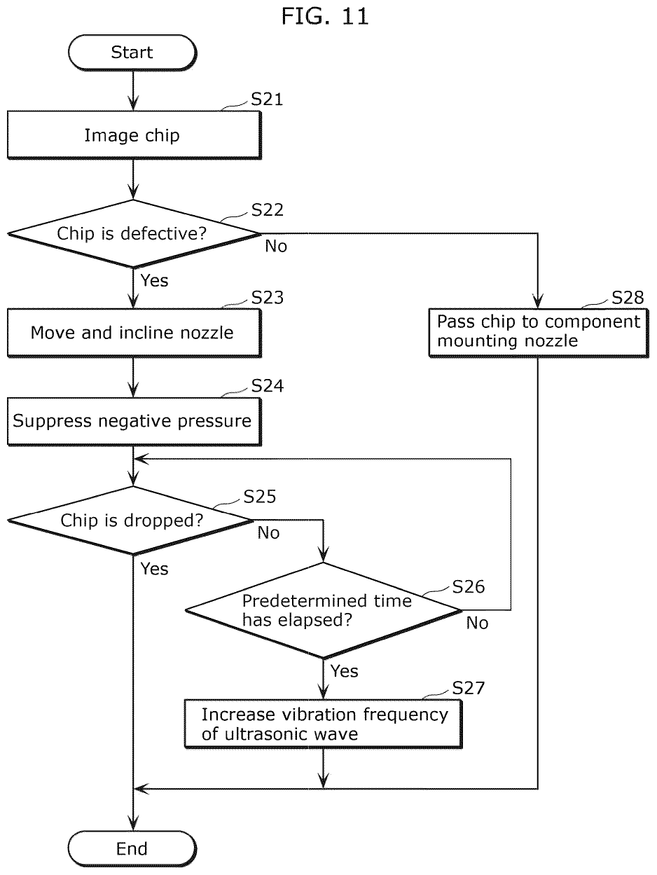

FIG. 11 is a flowchart showing an example of a processing operation performed by controller 101 in the present embodiment.

Controller 101 causes determination camera 22 to image chip 6a held by pickup nozzle 14a after the processing in step S6 shown in FIG. 7 is performed (step S21).

Then, controller 101 determines, based on an image captured by the imaging performed by determination camera 22, whether chip 6a is defective, that is, whether chip 6a is an error chip (step S22). Here, when controller 101 determines that chip 6a is not an error chip (no in step S22), controller 101 passes chip 6a to component mounting nozzle 20a from pickup nozzle 14a (step S28). In other words, controller 101 controls driver 154 to move and rotate pickup nozzle 14a, and thereby disposes chip 6a held by pickup nozzle 14a in a position in which chip 6a is passed to component mounting nozzle 20a.

On the other hand, when controller 101 determines that chip 6a is an error chip (yes in step S22), controller 101 moves pickup nozzle 14a above collection box 9, and inclines pickup nozzle 14a (step S23). In other words, pickup nozzle 14a is set to the chip collection state. Then, controller 101 controls negative pressure generator 153 to suppress the generation of the negative pressure (step S24). In other words, controller 101 causes negative pressure generator 153 to stop the generation of the negative pressure.

Thereafter, controller 101 determines whether chip 6a determined to be an error chip is dropped from pickup nozzle 14a (step S25). Here, when controller 101 determines that chip 6a is dropped (yes in step S25), controller 101 completes the processing on the error chip. On the other hand, when controller 101 determines that chip 6a is not dropped (no in step S25), controller 101 determines whether a predetermined time has elapsed since the processing in step S24, that is, the stop of the generation of the negative pressure (step S26). When controller 101 determines that the predetermined time has not elapsed (no in step S26), controller 101 repeatedly performs the processing in step S25. On the other hand, when controller 101 determines that the predetermined time has elapsed (yes in step S26), controller 101 causes ultrasonic generator 152 to increase the vibration frequency of ultrasonic waves (step S27). In this way, chip 6a determined to be an error chip is dropped from pickup nozzle 14a to be collected into collection box 9.

As described above, in the present embodiment, an error chip can be collected efficiently and effectively.

Although in the present embodiment, pickup nozzle 14a holds chip 6a in a non-contact manner, even when pickup nozzle 14a makes contact with chip 6a and holds it, ultrasonic waves may be used for dropping chip 6a.

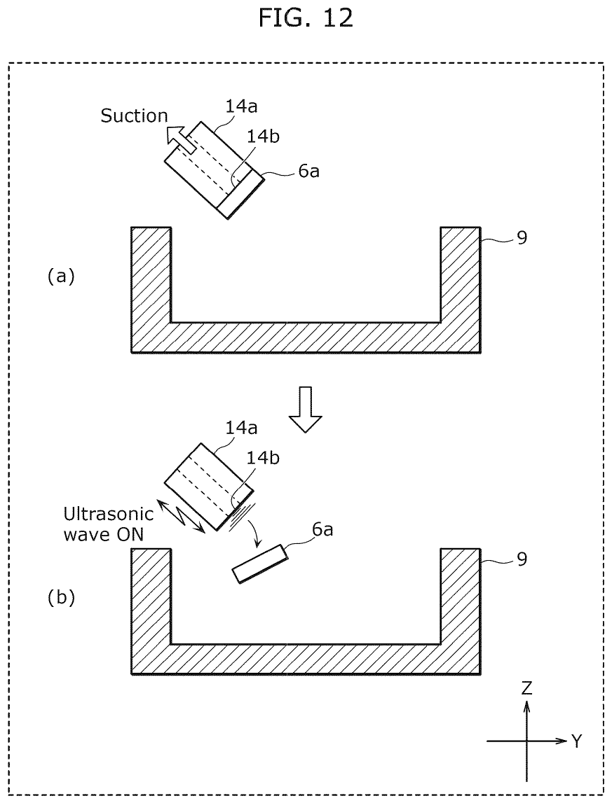

FIG. 12 is a diagram showing another example of the collection of an error chip. In the example shown in FIG. 12, pickup nozzle 14a makes contact with chip 6a determined to be an error chip, and holds chip 6a.

Controller 101 controls driver 154 to move pickup nozzle 14a in the Y axis direction, and disposes, as shown in part (a) in FIG. 12, chip 6a determined to be an error chip above collection box 9. Then, controller 101 sets the state of pickup nozzle 14a to the chip collection state by the rotation of pickup nozzle 14a around the X axis performed by driver 154. In the example shown in part (a) in FIG. 12, ultrasonic waves are not generated from around opening 14b of pickup nozzle 14a, and pickup nozzle 14a sucks chip 6a by vacuum suction using the negative pressure generated by suction.

Then, controller 101 controls, as shown in part (b) in FIG. 12, negative pressure generator 153 and ultrasonic generator 152 to stop the generation of the negative pressure and to generate ultrasonic waves. In this way, the repulsive force which moves chip 6a serving as the error chip away from opening 14b is exerted, and thus the error chip is dropped from pickup nozzle 14a. Then, the dropped error chip is collected into collection box 9.

In such a case, air is not discharged to collect an error chip, and thus it is possible to suppress the blowing up of dust. Consequently, it is possible to suppress the occurrence of a joint failure.

### (Other Variations)

Although the pickup system according to one or a plurality of aspects has been described above based on the embodiments, the present disclosure is not limited to these embodiments. Embodiments obtained by performing various types of variations conceivable by those skilled in the art on the embodiments and embodiments formed by combining constituent elements in the embodiments may be included in the present disclosure without departing from the spirit of the present disclosure.

For example, although in Embodiments 1 and 2 described above, chip 6a pushed upward is held in a non-contact manner, chip 6a which is not pushed upward may be held in a non-contact manner. Chip 6a to be picked up may be adhered on adhesive sheet 6b, or may be placed on a tray or the like. Even in these cases, controller 101 may start the generation of ultrasonic waves performed by ultrasonic generator 152 when the distance from opening 14b of pickup nozzle 14a to chip 6a reaches the specified distance.

In Embodiments 1 and 2 described above, the generation of ultrasonic waves is started, pickup nozzle 14a is lowered, and then negative pressure generator 153 generates the negative pressure. However, the timing at which the negative pressure is generated is not limited to this timing. For example, negative pressure generator 153 may constantly generate the negative pressure except when the error chip is collected. Negative pressure generator 153 may also generate the negative pressure simultaneously with the generation of ultrasonic waves, or may also generate the negative pressure before the generation of ultrasonic waves is started.

Although in Embodiments 1 and 2 described above, when component mounting nozzle 20a holds chip 6a, the lower surface of chip 6a makes contact with component mounting nozzle 20a, the lower surface of chip 6a may be thereafter washed.

Although in Embodiments 1 and 2 described above, pickup nozzle 14a holds chip 6a in a non-contact manner, component mounting nozzle 20a may also hold chip 6a in a non-contact manner as with pickup nozzle 14a.

Although in Embodiment 2 described above, determination camera 22 images the lower surface of chip 6a, determination camera 22 may image not only the lower surface but also the side surface of chip 6a, or may image the side surface of chip 6a instead of the lower surface. Cutting waste (such as Si) caused by dicing may be adhered to the side surface of chip 6a. Hence, chip 6a to which the cutting waste is adhered can be collected as an error chip. Determination camera 22 may image the lower surface of chip 6a from above. For example, determination camera 22 is disposed above pickup head 14 and pickup nozzle 14a located in pickup operation position P shown in FIG. 8. Then, determination camera 22 images, from above, the lower surface of chip 6a held by pickup nozzle 14a which is rotated, for example, 180 degrees around the X axis.

Although in Embodiment 2 described above, in order to collect an error chip, negative pressure generator 153 stops the generation of the negative pressure, negative pressure generator 153 may decrease the negative pressure being generated without stopping the generation of the negative pressure.

In Embodiment 1 or 2 described above, in the final step of pushing upward chip 6a which is being pushed upward, chip 6a may be pushed upward using one pin (that is, upward pushing pin 34a).

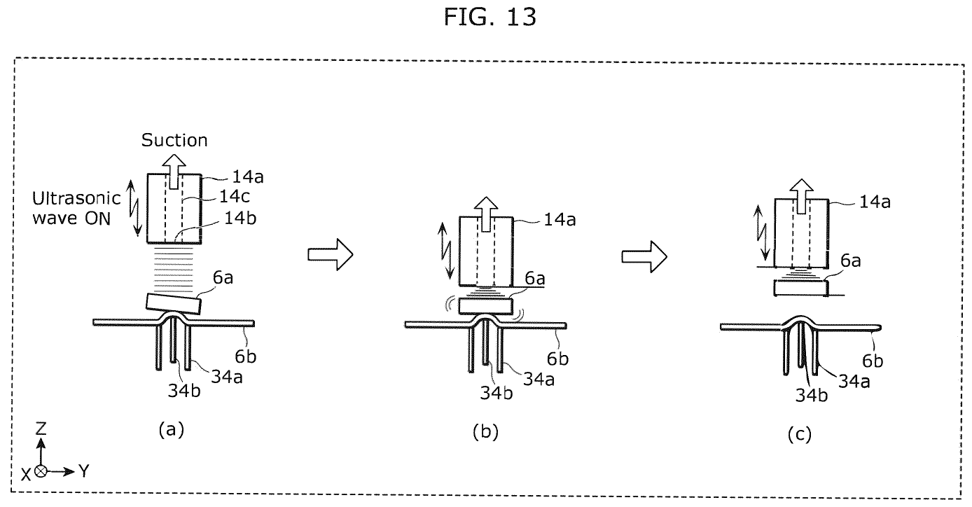

FIG. 13 is a diagram showing an example of the upward pushing of chip 6a.

As shown in parts (a) and (b) in FIG. 13, upward pusher 34 pushes chip 6a upward using a plurality of upward pushing pins 34a, and then pushes the center of chip 6a upward using one upward pushing pin 34b among upward pushing pins 34a in the final step. In this way, chip 6a can be moved by ultrasonic vibrations from above. Consequently, as shown in part (c) in FIG. 13, chip 6a can be picked up after parallelism between chip 6a and pickup nozzle 14a is corrected.

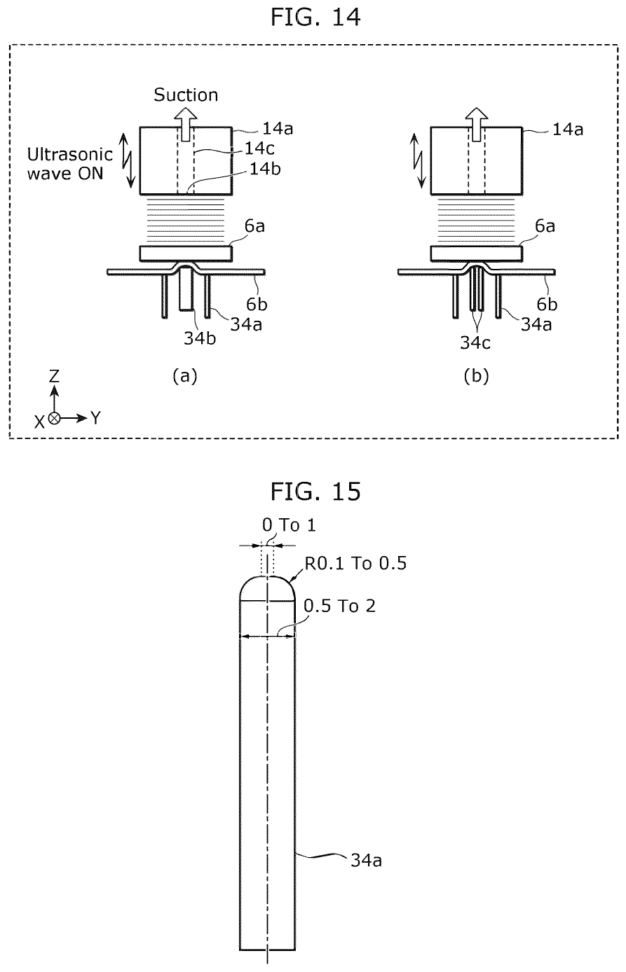

FIG. 14 is a diagram showing another example of the upward pushing of chip 6a.

When the outer shape of chip 6a is large, if chip 6a is pushed upward using one upward pushing pin 34b, chip 6a may be broken. Hence, in such a case, as shown in part (a) in FIG. 14, the diameter of upward pushing pin 34b may be larger than the diameter of other upward pushing pins 34a.

Controller 101 controls upward pusher 34 to perform the upward pushing of upward pushing pin 34b as described above. In other words, controller 101 controls upward pusher 34 to cause upward pushing pins 34a to push chip 6a upward, and then to cause only one upward pushing pin 34b among upward pushing pins 34a to further push chip 6a upward.

In this way, chip 6a is pushed upward by only one upward pushing pin 34b, and thus it is possible to easily adjust the inclination of chip 6a with the tip end of upward pushing pin 34b used as a support point. Consequently, the surfaces of chip 6a and pickup nozzle 14a opposite each other can be parallel to each other, and thus it is possible to cause pickup nozzle 14a to appropriately hold chip 6a.

As shown in part (b) in FIG. 14, upward pushing pin 34b may be formed with a plurality of upward pushing pins 34c each having a small diameter. Upward pushing pins 34c function as one upward pushing pin 34b. The total cross-sectional area of upward pushing pins 34c in the horizontal direction may be the same as that of upward pushing pin 34b, or may be the same as that of upward pushing pins 34a other than upward pushing pin 34b. In other words, upward pushing pin 34b pushes upward a part of the lower surface of chip 6a which is sufficiently small in area relative to the outer shape of chip 6a.

FIG. 15 is a diagram showing an example of the shape of upward pushing pin 34a. Dimensions shown in FIG. 15 are in mm, for example.

As shown in FIG. 15, the tip end of upward pushing pin 34a may be rounded. In this way, as compared with a pin having a flat tip end, the parallelism of the chip is corrected more appropriately. As compared with a pin having a sharp tip end, even when thin chip 6a is pushed upward, chip 6a is unlikely to be broken. The shape, the size, and the like of upward pushing pin 34a may be appropriately adjusted according to the outer shape, the thickness, and the like of chip 6a. Upward pushing pin 34a shown in FIG. 15 may be upward pushing pin 34b, or may be upward pushing pin 34c.

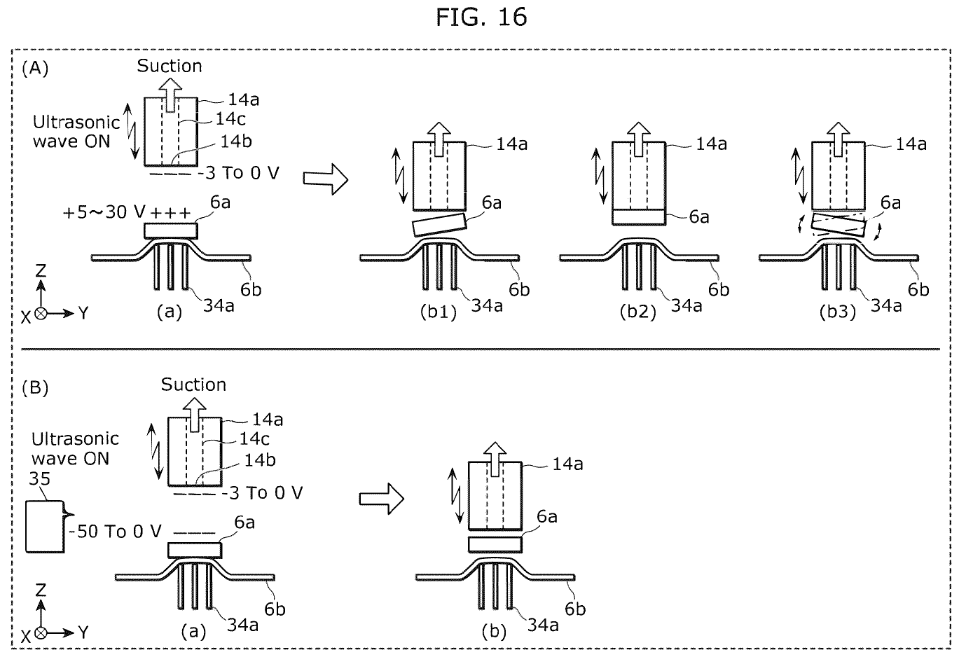

FIG. 16 is a diagram showing still another example of the upward pushing of chip 6a. Parts (a), (b1), (b2), and (b3) of section (A) in FIG. 16 show examples where chip 6a is held inappropriately, and parts (a) and (b) of section (B) in FIG. 16 show examples where chip 6a is held appropriately.

For example, as shown in part (a) of section (A) in FIG. 16, the surface of chip 6a is charged easily and positively by being peeled off from adhesive sheet 6b. Here, when the surface in which opening 14b of pickup nozzle 14a is provided is positively charged, chip 6a is held inappropriately as shown in part (b1), (b2), or (b3) of section (A) in FIG. 16. Specifically, as shown in part (b1), before chip 6a is held, one side of chip 6a is raised up. In other words, only one end of chip 6a is drawn to the side of pickup nozzle 14a. When chip 6a is held as shown in part (b2), chip 6a makes contact with pickup nozzle 14a and is sucked thereto. When chip 6a is held as shown in part (b3), chip 6a is not stabilized to flutter.

Hence, the surface on the side of opening 14b of pickup nozzle 14a and the upper surface of chip 6a may be charged to have the same polarity, and chip 6a may be picked up. Specifically, as shown in part (a) of section (B) in FIG. 16, electrical device 35 such as an ionizer is used to negatively change the surface of chip 6a. In this way, as shown in part (b) of section (B) in FIG. 16, it is possible to suppress contact between pickup nozzle 14a and chip 6a by electrical repulsion. Electrical device 35 such as an ionizer is controlled, for example, by controller 101. In other words, controller 101 controls the electrical device to charge at least one of the surface on the side of opening 14b of pickup nozzle 14a or the surface of chip 6a on the side of pickup nozzle 14a, and thereby causes the surface on the side of opening 14b of pickup nozzle 14a and the surface of chip 6a described above to have the same polarity.

In this way, the surface on the side of opening 14b of pickup nozzle 14a and the surface of chip 6a on the side of pickup nozzle 14a have the same polarity, and thus it is possible to generate an electrical repulsive force therebetween. Consequently, it is possible to suppress contact between chip 6a and pickup nozzle 14a.

In each of the embodiments described above, controller 101 and the like may be formed by dedicated hardware, or may be realized by executing software programs suitable for controller 101. A program executor such as a central processing unit (CPU) or a processor may read and execute software programs recorded in a recording medium such as a hard disk or a semiconductor memory to realize controller 101. Here, the software which realizes controller 101 and the like in the embodiment causes a computer to execute, for example, the steps in the flowchart shown in FIG. 7 or 11.

The following cases are also included in the present disclosure.

(1) Specifically, controller 101 may be a computer system which includes a microprocessor, a read only memory (ROM), a random access memory (RAM), a hard disk unit, a display unit, a keyboard, a mouse, and the like. In the ROM or the hard disk unit, computer programs are stored. The microprocessor is operated according to the computer programs, and thus controller 101 achieves its functions. Here, the computer programs are formed by combining a plurality of instruction codes indicating commands to the computer in order to achieve predetermined functions.

(2) Controller 101 may be formed with one system large scale integration (LSI) circuit. The system LSI circuit is a super-multifunctional LSI circuit which is manufactured by integrating a plurality of constituent units on one chip, and is specifically a computer system which includes a microprocessor, a ROM, a RAM, and the like. In the RAM, computer programs are stored. The microprocessor is operated according to the computer programs, and thus the system LSI circuit achieves its functions.

(3) Controller 101 may be formed with a removable IC card or a single module. The IC card or the module is a computer system which includes a microprocessor, a ROM, a RAM and the like. The IC card or the module may include the super-multifunctional LSI circuit described above. The microprocessor is operated according to computer programs, and thus the IC card or the module achieves its functions. The IC card or the module may be tamper-resistant.

(4) The present disclosure may be the method described above. The present disclosure may be computer programs which realize the method using a computer, or may be digital signals of computer programs.

The present disclosure may be computer-readable recording media such as a flexible disk, a hard disk, a compact disc (CD)-ROM, a DVD, a DVD-ROM, a DVD-RAM, a Blu-ray (registered trademark) Disc (BD), and a semiconductor memory in which computer programs or digital signals are recorded. The present disclosure may be digital signals recorded in these recording media.

The present disclosure may be computer programs or digital signals which are transmitted via a telecommunication line, a wireless or wired communication line, a network such as the Internet, data broadcasting, or the like.

The present disclosure may be programs or digital signals which are recorded in a recording medium and transmitted or are transmitted via a network or the like, and are performed by a separate independent computer system.

### INDUSTRIAL APPLICABILITY

For example, the present disclosure can be utilized for a system and the like which pick up a component to perform an operation using the component.

### REFERENCE SIGNS LIST

1, 1a component mounting device
2 base
3 component supplier
3a holding table
5 substrate holder
5a conveyance rail
6 semiconductor wafer unit
6a chip (component)
6b adhesive sheet
7 substrate
9 collection box
11 frame
11a support post
11b Y axis frame
12 Y axis driving mechanism
13 component mounter
13a movement plate
13b ascent/descent mechanism
13c ascent/descent plate
14 pickup head
14a pickup nozzle (holding tool)
14b opening
14c flow path
15 component holder
15a arm
15b pickup head movement mechanism
15c holding main body
20 mounting unit
20a component mounting nozzle
21 pickup camera
22 determination camera
31 XY table mechanism
32 movement plate
33 support member
34 upward pusher
100, 100a pickup system
101 controller
152 ultrasonic generator
153 negative pressure generator
154 driver

What is claimed is:

1. A pickup system comprising:
a holding tool that includes an opening, and is configured to ascend and descend;
a negative pressure generator that generates a negative pressure around the opening of the holding tool;
an ultrasonic generator that generates an ultrasonic wave from around the opening; and
a controller that controls the negative pressure generator and the ultrasonic generator,
wherein the controller:
causes the ultrasonic generator to start the generating of the ultrasonic wave when a distance from the opening of the holding tool to a component adhered on an adhesive sheet reaches, by the ascending and descending of the holding tool, a distance specified beforehand; and
causes the holding tool to hold the component in a non-contact manner using a suction force generated by the negative pressure around the opening and a repulsive force generated by the ultrasonic wave around the opening, and
the distance specified is a distance that is specified according to a frequency of the ultrasonic wave generated by the ultrasonic generator.

2. The pickup system according to claim 1,
wherein the distance specified is a distance from the opening of the holding tool to a part other than an antinode of the ultrasonic wave generated by the ultrasonic generator.

3. The pickup system according to claim 1,
wherein the controller separates the component held by the holding tool from the holding tool by controlling vibrations of the ultrasonic wave generated by the ultrasonic generator in a state where the generating of the negative pressure by the negative pressure generator is suppressed.

4. The pickup system according to claim 3,
wherein the controller separates the component from the holding tool by suppressing the generating of the negative pressure by the negative pressure generator and then increasing a vibration frequency of the ultrasonic wave generated by the ultrasonic generator.

5. The pickup system according to claim 4,
wherein the controller increases the vibration frequency of the ultrasonic wave generated by the ultrasonic generator when the component is not dropped from the holding tool after a predetermined time has elapsed since the generating of the negative pressure by the negative pressure generator is suppressed.

6. The pickup system according to claim 1, further comprising:
an upward pusher that pushes the component adhered on the adhesive sheet upward from below via the adhesive sheet,
wherein the controller further controls the upward pusher.

7. The pickup system according to claim 6,
wherein the controller causes the ultrasonic generator to start the generating of the ultrasonic wave when the component is pushed upward by the upward pusher.

8. The pickup system according to claim 7,
wherein the upward pusher includes a plurality of upward pushing pins, and
the controller causes the plurality of upward pushing pins to push the component upward and then causes only one of the plurality of upward pushing pins to further push the component upward by controlling the upward pusher.

9. The pickup system according to claim 1,
wherein the controller charges at least one of the opening of the holding tool or a surface of the component by controlling an electrical device to cause the opening of the holding tool and the surface of the component to have a same polarity, the surface facing the holding tool.

10. A pickup method comprising:
causing a negative pressure generator to generate a negative pressure around an opening of a holding tool that is configured to ascend and descend;
causing an ultrasonic generator to generate an ultrasonic wave from around the opening; and
causing the holding tool to hold a component in a non-contact manner using a suction force generated by the negative pressure around the opening and a repulsive force generated by the ultrasonic wave around the opening,
wherein in the generating of the ultrasonic wave, the ultrasonic generator is caused to start the generating of the ultrasonic wave when a distance from the opening of the holding tool to the component adhered on an adhesive sheet reaches, by the ascending and descending of the holding tool, a distance specified beforehand, and
the distance specified is a distance that is specified according to a frequency of the ultrasonic wave generated by the ultrasonic generator.
